(19) United States
(12) Patent Application Publication
(10) Pub. No.: US 2004/0245595 A1
(43) Pub. Date: Dec. 9, 2004

(54) Semiconductor device

(76) Inventor: Yoshihiro Taniguchi, Sakata-shi (JP)

Correspondence Address: HARNESS, DICKEY & PIERCE, P.L.C., P.O. BOX 828, BLOOMFIELD HILLS, MI, 48303, US

(21) Appl. No.: 10/760,175

(22) Filed: Jan. 16, 2004

(30) Foreign Application Priority Data
Jan. 17, 2003 (JP) 2003-009933

(51) Int. Cl. H01L 29/00

(52) U.S. Cl. 257/499

(57) ABSTRACT

A semiconductor device is provided which has high reliability and which can reduce electrical power consumption. The semiconductor device has an element isolation region formed in a semiconductor substrate, and a depth X of the element isolation region and a width Y thereof isolating adjacent doped layers from each other satisfy an equation represented by X/Y=1.33 to 1.67.

### BACKGROUND OF THE INVENTION

1. Technical Field of the Invention

The present invention relates to semiconductor devices which have high reliability and which can reduce electrical power consumption.

2. Description of the Related Art

In general, a semiconductor device is composed of elements, such as a substrate, a gate electrode, and a member for an element isolation region, and the elements described above are formed of materials different from each other. Accordingly, since the hardness and coefficients of thermal expansion are different among the materials, stress is likely to be concentrated at a region in which components composed of different materials are in contact with each other, and as a result, defects may occur in some cases.

For example, when crystal defects are generated in a semiconductor substrate, data-writing and/or data-erasing errors occur, and as a result, the reliability of a semiconductor device may be degraded in some cases. In addition, when the defects described above are generated, a leak current may be increased in some cases. The increase in leak current described above interferes with reduction of electrical power consumption.

Accordingly, an object of the present invention is to provide a semiconductor device which has high reliability and which can reduce electrical power consumption.

### SUMMARY

A semiconductor device of the present invention comprises a semiconductor layer which contains an element isolation region and adjacent doped layers isolated from each other by the element isolation region, wherein a depth X of the element isolation region and a width Y thereof isolating the adjacent doped layers from each other satisfy the equation X/Y=1.33 to 1.67.

According to the semiconductor device of the present invention, since the depth X of the element isolation region and the width Y thereof isolating the adjacent doped layers from each other satisfy the equation represented by X/Y=1.33 to 1.67, a stress per unit area applied to the semiconductor layer from the element isolation region can be reduced. Accordingly, stress is prevented from being concentrated at a joint portion between the element isolation region and the semiconductor layer, and hence crystal defects can be prevented from being generated in the semiconductor layer. As a result, since data-writing and/or data-erasing errors and the generation of a leak current can be prevented, a semiconductor device is obtained which has high reliability and which can reduce electrical power consumption.

When X/Y is less than 1.33, the element isolation region may not be able to sufficiently electrically isolate doped layers from each other in some cases. On the other hand, when X/Y is more than 1.67, stress applied from the element isolation region to the semiconductor layer is increased, and as a result, crystal defects may be generated therein in some cases.

In the present invention, the width of the element isolation region indicates a width at the topmost surface thereof. In addition, in this embodiment, although not shown in the figure, when four sides of the element isolation region are surrounded by doped layers, the width of the element isolation region 19 is a width at the topmost surface thereof having a shorter distance between the doped layers facing each other.

The semiconductor device of the present invention may have the following structures.

The depth X of the element isolation region described above may be in the range of from 0.32 to 0.40 μm.

The element isolation region may be a trench element isolation region. The trench element isolation region is formed by filling an insulating layer in a trench provided in a semiconductor layer. Accordingly, when the element isolation region described above is a trench element isolation region, a large stress is liable to be applied in the vicinity of the element isolation region of the semiconductor layer. However, according to the present invention, due to the structures described above, even when the element isolation region is a trench element isolation region, stress is prevented from being concentrated at the joint portion between the element isolation region and the semiconductor layer, and as a result, crystal defects can be reliably prevented from being generated in the semiconductor layer.

In the case described above, the element isolation region may comprise a trench formed in the semiconductor layer and an insulating layer provided in the trench.

The insulating layer may be formed using an HDP-CVD method, a TEOS plasma CVD method, or an SOG method.

When the insulating layer is formed by a TEOS plasma CVD method or an SOG method, stress applied from the insulating layer to the semiconductor layer is smaller than that generated when the insulating layer is formed by an HDP-CVD method. Hence, crystal defects can be reliably prevented from being generated in the semiconductor layer.

In addition, since an HDP-CVD method generally forms a dense insulating layer, when the insulating layer described above is formed thereby, a large stress is applied to the semiconductor layer from the insulating layer as compared to that generated when the insulating layer is formed by a TEOS plasma method or an SOG method. However, according to the present invention, stress can be prevented from being concentrated at the joint portion between the insulating layer and the semiconductor layer. Hence, even when the insulating layer is formed by an HDP-CVD method, crystal defects can be reliably prevented from being generated in the semiconductor layer.

The adjacent doped layers may be two doped layers having the same conductivity. According to the structure described above, for example, even when a conductive layer is formed in the vicinity of the two doped layers, a parasitic bipolar transistor can be prevented from being formed from the two doped layers and the conductive layer. As a result, stable electrical properties can be obtained.

The adjacent doped layers may be two doped layers which have the same conductivity and which are contained in respective memory cells adjacent to each other. According to the structure described above, for the same reason described in the above, the memory cells adjacent to each other can be electrically isolated from each other, and as a result, stable electrical properties can be obtained for each memory cell.

### BRIEF DESCRIPTION OF THE DRAWINGS

FIG. 1 is a schematic cross-sectional view showing an element isolation region and a peripheral region thereof, the element isolation region included in a semiconductor device of one embodiment according to the present invention.

FIG. 2 is a plan view showing a layout of an SRAM cell according to the present invention.

FIG. 3 is an enlarged plan view of a region A100 of the SRAM cell shown in FIG. 2.

FIG. 4 is a cross-sectional view of the SRAM cell taken along the line B-B shown in FIG. 2.

FIG. 5 is a cross-sectional view of the SRAM cell taken along the line C-C shown in FIG. 2.

FIG. 6 is an equivalent circuit of an SRAM.

FIG. 7 is a plan view showing gate-gate connection layers and source/drain regions of the SRAM cell shown in FIG. 2.

FIG. 8 is a plan view showing drain-drain connection layers of the SRAM cell shown in FIG. 2.

FIG. 9 is a plan view showing drain-gate connection layers of the SRAM cell shown in FIG. 2.

### DETAILED DESCRIPTION

Hereinafter, preferred embodiments of the present invention will be described with reference to drawings.

1. Structure of Semiconductor Device

Structure of Element Isolation Region

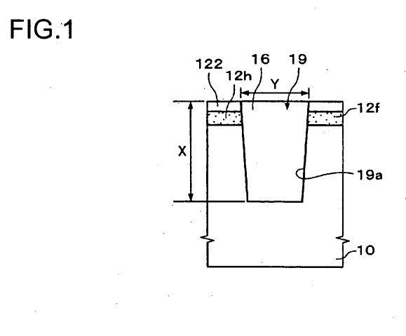

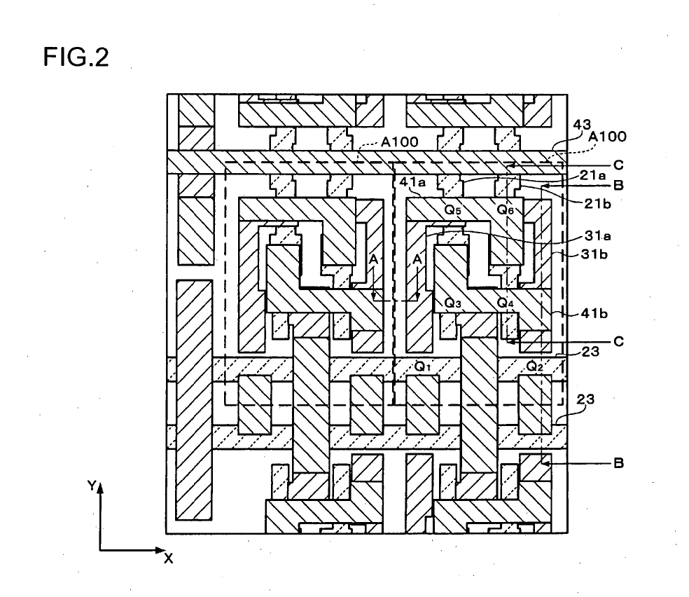

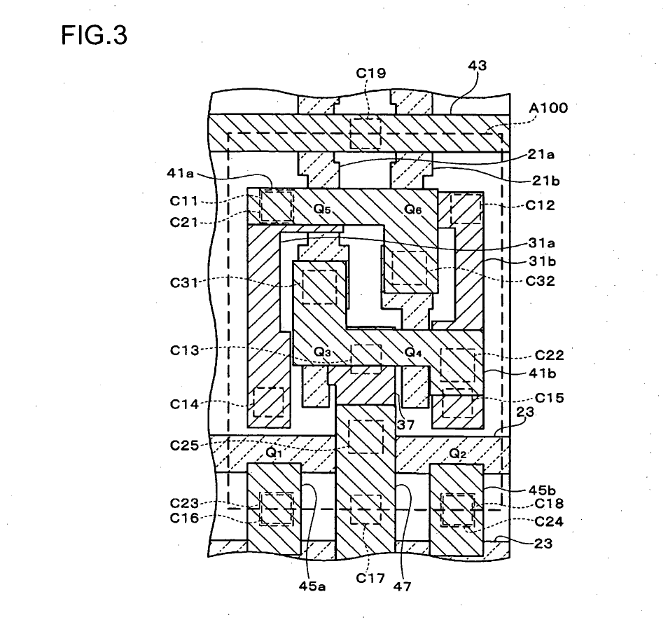

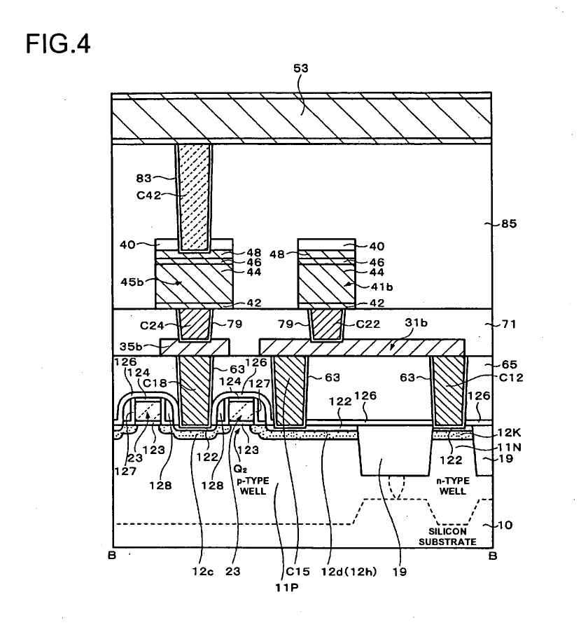

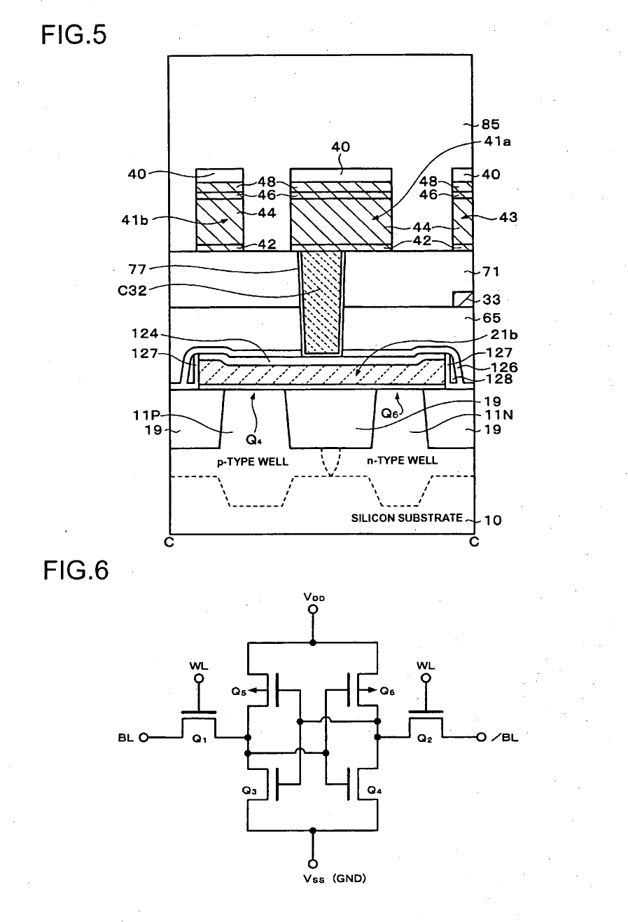

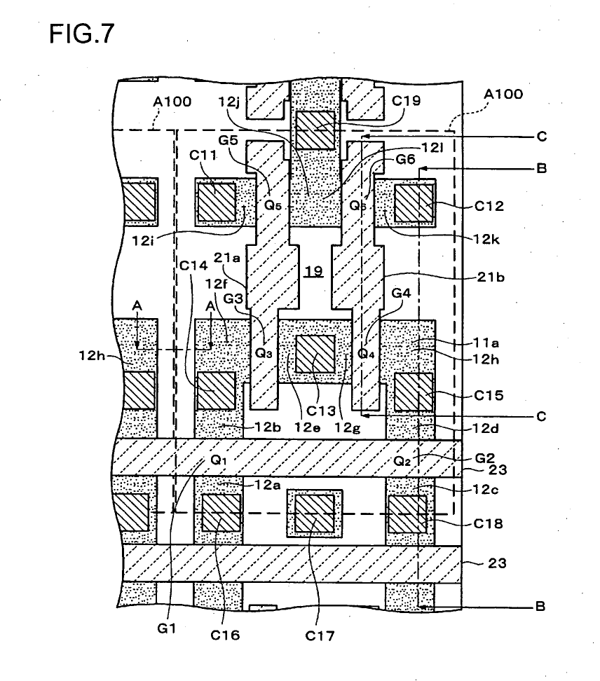

FIG. 1 is a schematic cross-sectional view of an element isolation region 19 and a peripheral region thereof, the element isolation region 19 included in a semiconductor device of one embodiment according to the present invention. FIG. 2 is a schematic cross-sectional view showing an example of a semiconductor memory device including the element isolation regions 19 shown in FIG. 1. In this embodiment, the case will be described in which the semiconductor memory device shown in FIG. 2 is an SRAM. FIGS. 2 and 7 to 9 are plan views each showing an example of a layout of a memory cell (hereinafter referred to as an “SRAM cell”) of a full CMOS SRAM of this embodiment. FIG. 3 is an enlarged view of a region A100 shown in FIG. 2, and FIG. 7 is a view showing a layer (active region and the like) under the region shown in FIG. 3. FIG. 4 is a cross-sectional view of the SRAM cell taken along the line B-B shown in FIG. 2, and FIG. 5 is a cross-sectional view of the SRAM cell taken along the line C-C shown in FIG. 2. FIG. 6 is an equivalent circuit of an SRAM.

FIG. 1 is a schematic cross-sectional view of the SRAM cell taken along the line A-A shown in FIGS. 2 and 7. In FIG. 1, a semiconductor substrate 10, the element isolation region 19, and the peripheral region thereof are only shown, and layers (insulating layers, wiring layers, and the like) formed above the semiconductor substrate 10 are not shown.

The semiconductor device of this embodiment includes the element isolation region 19. The element isolation region 19 is formed in the semiconductor substrate 10 made, for example, of a silicon substrate and has a trench element isolation structure.

The element isolation region 19 is formed by filling an insulating layer 16 in a trench 19a. The insulating layer 16 may be formed, for example, by a high density plasma CVD (HDP-CVD), a low pressure plasma CVD (LPCVD), a thermal CVD, a TEOS plasma CVD, or an SOG method.

The element isolation region 19 isolates doped layers from each other. In this embodiment, the element isolation region 19 isolates a doped layer 12f from a doped layer 12h along the line A-A shown in FIGS. 2 and 7, which doped layers have the same conductivity and are formed in respective memory cells A100 adjacent to each other.

In this embodiment, a width Y of the element isolation region 19 indicates a width at the topmost surface thereof as shown in FIG. 1. In particular, the width Y of the element isolation region 19 is a width of an element isolation region formed between the doped layer 12f and the doped layer 12h, which have the same conductivity and which are formed in respective memory cells adjacent to each other. In addition, although not shown in the figure in this embodiment, when four sides of the element isolation region 19 are surrounded by doped layers, the width of the element isolation region 19 indicates a shorter distance between doped layers facing each other.

A depth X of the element isolation region 19 and the width Y of the element isolation region 19 isolating the doped layer 12f from the doped layer 12h adjacent thereto satisfy an equation represented by X/Y=1.33 to 1.67. When X/Y is less than 1.33, the doped layers 12f and 12h may not be sufficiently electrically isolated from each other with the element isolation region 19 in some cases. On the other hand, when X/Y is more than 1.67, stress applied to the semiconductor substrate 10 from the element isolation region 19 is increased, and as a result, crystal defects may be generated in the semiconductor substrate 10 in some cases.

In addition, the depth X of the element isolation region 19 is preferably in the range of from 0.32 to 0.40 μm.

Structure of Memory Cell A100

Next, the structure of the memory cell A100 will be described in which the element isolation region 19 shown in FIG. 1 is formed.

Plan Structure

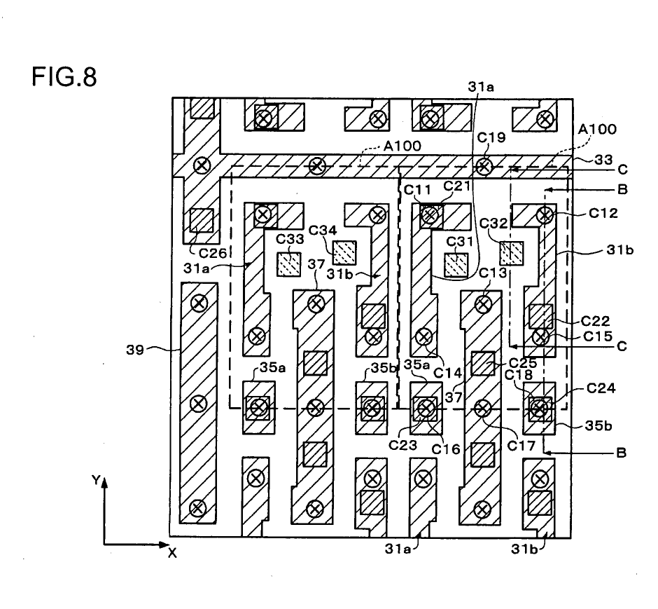

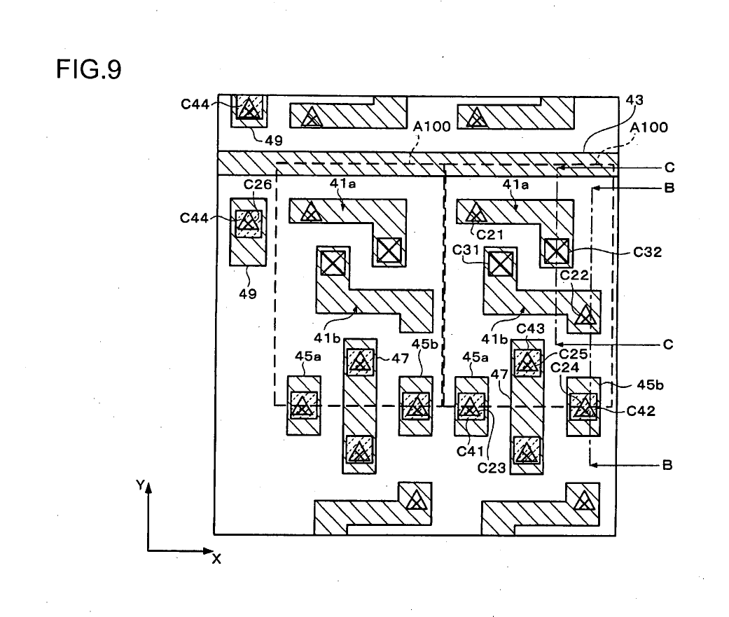

FIG. 2 is a plan view showing a first, a second, and a third layer of an SRAM cell of this embodiment, and FIG. 3 is an enlarged view of the region A100 shown in FIG. 2. The SRAM cell mentioned above has the structure formed of a first, a second, and a third conductive layer provided above the semiconductor substrate 10 (described later) made of a silicon substrate with interlayer insulating layers interposed between the individual layers. At the first layer, as shown in FIG. 7, there are provided gate-gate connection layers 21a and 21b and a sub-word wiring line (sub-word line) 23, which are formed of polycrystal silicon. At the second layer, as shown in FIG. 8, drain-drain connection layers 31a and 31b and the like are provided. At the third layer, as shown in FIG. 9, drain-gate connection layers 41a and 41b and the like are provide. Above the structure shown in FIG. 7, the structure shown in FIG. 8 is located, and the structure shown in FIG. 9 is located above the aforementioned structure. The structures described above are collectively shown in FIG. 2.

In FIG. 2, a portion forming a flip-flop is primarily shown. This portion in the region A100 will be described in detail. The region A100 indicates a region in which one memory cell is formed. The region A100 in another figure is also the same as described above. An equivalent circuit of a CMOS SRAM, which is made of six transistors provided in the region A100, is shown in FIG. 6.

In the region A100, as shown in FIGS. 2, 3, and 6, six transistors Q₁ to Q₆ are provided to form one memory cell. Active regions isolated from each other are formed in an n-type well 11N (see FIG. 4), a load transistor Q₅ is formed in one active region, and a load transistor Q₆ is formed in the other active region. In addition, active regions isolated from each other are formed in a p-type well 11P (see FIG. 4), a transfer transistor Q₁ and a drive transistor Q₃ are formed in one common active region, and a transfer transistor Q₂ and a drive transistor Q₄ are formed in the other common active region.

The drive transistor Q₃ and the load transistor Q₅ form a CMOS inverter, the drive transistor Q₄ and the load transistor Q₆ form a CMOS inverter, and the inverters thus formed are connected to each other to form a flip-flop circuit.

At the first layer, as shown in FIGS. 2, 3, and 7, the gate-gate connection layers 21a and 21b each have a linear pattern. In addition, as shown in FIG. 7, portions at which the gate-gate connection layers 21a and 21b and the sub-word wiring layer 23 intersect the active regions form gate electrodes G1, G2, G3, G4, G5, and G6. That is, the gate-gate connection layer 21a connects the gate electrode G3 of the drive transistor Q₃ to the gate electrode G5 of the load transistor Q₅.

In addition, the gate-gate connection layer 21b connects the gate electrode G4 of the drive transistor Q₄ to the gate electrode G6 of the load transistor Q₆. The gate length of the drive transistors Q₃ and Q₄ is, for example, 0.18 μm. The gate length of the load transistors Q₅ and Q₆ is, for example, 0.20 μm.

The sub-word wiring layer 23 is activated or inactivated by a main word wiring layer (main word line) 43 which is formed above. The sub-word wiring layer 23 connects the gate electrode G1 of the transfer transistor Q₁ to the gate electrode G2 of the transfer transistor Q₂. The gate length of the transistors described above is, for example, 0.24 μm.

At the second layer, as shown in FIGS. 2, 3, and 8, the drain-drain connection layers 31a and 31b each have a linear pattern and connect the drains of the individual CMOSs to each other. The drain-drain connection layers 31a and 31b are formed on a first interlayer insulating layer 65 (see FIG. 4) which is provided above the semiconductor substrate 10. Furthermore, as shown in FIG. 7, in the first interlayer insulating layer 65, first contact portions C11 to C19 (hereinafter referred to as “contact portions C11 to C19”) are formed.

The drain-drain connection layer 31a connects the drain region 12f of the drive transistor Q₃ to the drain region 12i of the load transistor Q₅ through the contact portions C14 and C11. In addition, the drain-drain connection layer 31b connects the drain region 12h of the drive transistor Q₄ to the drain region 12k of the load transistor Q₆ through the contact portions C15 and C12.

In addition, as shown in FIG. 8, at the same level as that of the drain-drain connection layers 31a and 31b, first contact pad layers 35a and 35b, a V_{SS} local wiring layer 37, and a V_{DD} wiring layer 33 are formed so as to overlap the contact portions C16 to C19. The drain-drain connection layers 31a and 31b, the first contact pad layers 35a and 35b, the V_{SS} local wiring layer 37, and the V_{DD} wiring layer 33 form a second conduction layer. These layers are formed, for example, of a metal layer of a high melting point metal, a nitride layer of a high melting point metal, a laminate of a metal and a high melting point metal, or a laminate of a metal layer and a nitride layer, each formed of a high melting metal. In particular, for example, titanium, titanium nitride, a laminate of titanium and aluminum, or a laminate of titanium and titanium nitride may be mentioned.

At the third layer, as shown in FIGS. 2, 3, and 9, the drain-gate connection layers 41a and 41b are formed above a second interlayer insulating layer 71 (shown in FIG. 4), and in the second interlayer insulating layer 71, second contact portions. C21 to C26 (hereinafter referred to as “contact portions C21 to C26”) are formed. In addition, third contact portions C31 and C32 (hereinafter referred to as “contact portions C31 and C32”) penetrating the first interlayer insulating layer 65 and the second interlayer insulating layer 71 are formed.

The gate-gate connection layer 21a and the drain-drain connection layer 31b are connected to each other with the drain-gate connection layer 41b through the contact portions C22 and C31. In addition, the gate-gate connection layer 21b and the drain-drain connection layer 31a are connected to each other with the drain-gate connection layer 41a through the contact portions C21 and C32.

Furthermore, as shown in FIG. 9, at the same level as those of the drain-gate connection layers 41a and 41b, second contact pad layers 45a and 45b, a V_{SS} contact pad layer 47, and a V_{DD} contact pad layer 49 are formed. The second contact pad layers 45a and 45b, the V_{SS} contact pad layer 47, and the V_{DD} contact pad layer 49 are formed so as to overlap the contact pad portions C231 C24, C25, and C26, respectively, and above the layers described above, fourth contact portions C41 to C44 (hereinafter referred to as “contact portions. C41 to C44”) are formed. The contact portion C41 is formed for connecting a bit wiring layer (bit line) to a source/drain region 12a of the transfer transistor Q₁, and the contact portion C42 is formed for connecting a bit wiring layer (bit line/BL) 53 (see FIG. 4), which is an upper wiring layer, to a source/drain region 12c of the transfer transistor Q₂. The source/drain region means a region which functions as a source or a drain. The contact portion C43 is formed for connecting the p-type well 11P (see FIG. 4) to a V_{SS} wiring layer (not shown), and the contact portion C44 is formed for connecting the n-type well 11N (see FIG. 4) to a V_{DD} wiring film (not shown).

Cross-Sectional Structure

Next, with reference to FIGS. 4, 5, and 7, a cross-sectional structure of the SRAM cell of this embodiment will be described.

In the SRAM cell of this embodiment, the gate-gate connection layer 21a and 21b, the drain-drain connection layers 31a and 31b, and the drain-gate connection layers 41a and 41b are formed in that order above the semiconductor substrate 10 with the interlayer insulating layers provided between the individual layers.

In the semiconductor substrate 10, as shown in FIGS. 4 and 7, the n-type well 11N, the p-type well 11P, the doped layers (source/drain regions) 12a to 12l, and the element isolation region 19 are formed. The p-type well 11P and the n-type well 11N are electrically isolated by the element isolation region 19, and in addition, the element isolation region 19 is formed along the peripheries of the active regions of the MOS transistors.

Referring to FIG. 4, the cross-section along the line B-B shown in FIG. 2 will be described.

In the n-type well 11N, the drain region 12k of the load transistor Q₆ is formed, and in the p-type well 11P, the drain region 12h of the drive transistor Q₄ and the source/drain region 12d of the transfer transistor Q₂ are formed. On the individual source/drain regions 12a to 12l, silicide layers 122 are formed, and on the surfaces thereof, insulating layers 126 made of silicon nitride are formed.

Above the semiconductor substrate 10 on which the MOS transistors are formed, the sub-word wiring layers 23 are formed. In addition, above the semiconductor substrate 10, the first interlayer insulating layer 65 is formed. In the first interlayer insulating layer 65, the contact portions C18, C15, and C12 connected to the respective source/drain regions 12c, 12d (12h), and 12k are formed.

On the source/drain region 12d (12h), the silicide layer 122 is formed. The contact portion C15 is composed of a nitride layer of a high melting point metal provided so as to be in contact with the silicide layer 122 and a plug layer which is formed on the nitride layer and is filled in a first contact hole 63. The plug layer is formed of tungsten or the like. The nitride layer of a high melting point metal described above serves primarily as a barrier layer.

In addition, the drain-drain connection layer 31b for connecting the drain region 12h of the drive transistor Q₄ to the drain region 12k of the load transistor Q₆ and the first contact pad layer 35b are formed on the first interlayer insulating layer 65. The first contact pad layer 35b is formed in the same step as for forming the drain-drain connection layer 31b and is connected to the source/drain region 12c of the transfer transistor Q₂ through the contact portion C18.

In addition, on the first interlayer insulating layer 65, the second interlayer insulating layer 71 is formed. In the second interlayer insulating layer 71, the contact portions C22 and C24 are formed. The contact portion such as the contact portion C22 or C24 has the same structure as that of the first contact portion and is formed of a plug layer made of tungsten or the like filled in a second contact hole 79.

Above the second interlayer insulating layer 71, the drain-gate connection layer 41b is formed. The drain-gate connection layer 41b is connected to the drain-drain connection layer 31b through the contact portion C22. In addition, the second contact pad layer 45b connecting the contact portion C24 to the contact portion C42 is formed in the same step as that for the drain-gate connection layer 41b. Furthermore, since the contact portion C42 is connected to the bit wiring layer 53 (bit line/BL shown in FIG. 6) used as the upper wiring layer, the source/drain region 12c of the transfer transistor Q₂ and the bit wiring layer 53 are connected to each other. In the bit wiring layer 53, a signal flows which is complementary to a signal flowing in another bit wiring layer (bit line BL in FIG. 6).

The drain-gate connection layer 41b is formed, for example, of a nitride layer 42 of a high melting point metal, a metal layer 44 made of aluminum, copper, or an alloy thereof, a metal layer 46 made of a high melting point metal, and a nitride layer 48 of a high melting point metal in that order from the semiconductor substrate 10 side. In particular, the drain-gate connection layer 41b may be formed of titanium nitride as the nitride layer 42 of a high melting point metal, aluminum as the metal layer 44, titanium as the metal layer 46 of a high melting point metal, and titanium nitride as the nitride layer 48 of a high melting point metal. In addition, the contact portion C42 has the same structure as that of the first contact portion and is formed of a plug layer made of tungsten or the like filled in a fourth contact hole 83.

In addition, on the second interlayer insulating layer 71, as shown in FIG. 4, a third interlayer insulating layer 85 is formed, and the bit wiring layer 53 is formed on the third interlayer insulating layer 85. The third interlayer insulating layer 85 is formed, for example, of silicon oxide, FSG (fluorine doped silicon oxide), or a laminate thereof.

Next, with reference to FIGS. 2 and 5, the cross-section along the line C-C in FIG. 2 will be described. The same reference numerals of the constituent elements shown in FIG. 4 designate the same constituent elements shown in FIG. 5, and detailed descriptions thereof will be omitted.

Above the p-type well 11P and the n-type well 11N which are electrically isolated from each other by the element isolation region 19, the gate-gate connection layer 21b is formed. In addition, on the p-type well 11P, the drive transistor Q₄ is formed, and on the n-type well 11N, the load transistor Q₆ is formed. The drive transistor Q₄ and the load transistor Q₆ are connected to each other with the gate-gate connection layer 21b.

On the gate-gate connection layer 21b, a silicide layer 124 and the insulating layer 126 made of silicon nitride or the like are provided in that order, and on the surface thereof, the first interlayer insulating layer 65 and the second interlayer insulating layer 71 are further formed. In addition, the drain-gate connection layer 41a is formed above the second interlayer insulating layer 71. Furthermore, the contact portion C32 is formed which penetrates the first interlayer insulating layer 65 and the second interlayer insulating layer 71, and the gate-gate connection layer 21b and the drain-gate connection layer 41a are connected to each other through the contact portion C32. The contact portion C32 has the same structure as that of the first contact portion and is formed of a plug layer of tungsten or the like filled in a third contact hole 77.

Connections Among Constituent Elements

Next, with reference to FIGS. 3, 6, and 7, the connections among the constituent elements will be described.

The transfer transistor Q₁ has the n⁺-type source/drain regions 12a and 12b at two sides of the sub-word wiring layer 23. The source/drain region 12a is connected to the bit wiring layer 53 (bit line/BL in FIG. 6) through the contact portion C16, the first contact pad layer 35a, the contact portion C23, the second contact pad 45a, and the contact portion C41.

The transfer transistor Q₂ has the n⁺-type source/drain regions 12c and 12d at two sides of the sub-word wiring layer 23. The source/drain region 12c is connected to the bit wiring layer 53 (bit line/BL in FIG. 6) through the contact portion C18, the first contact pad layer 35b, the contact portion C24, the second contact pad 45b, and the contact portion C42.

The drive transistor Q₃ has the n⁺-type source region 12e and the n⁺-type drain region 12f at two sides of the gate-gate connection layer 21a. The source region 12e is connected to the V_{SS} wiring layer (corresponding to V_{SS} in FIG. 6) through the contact portion C13, the V_{SS} local wiring layer 37, the contact portion C25, the V_{SS} contact pad 47, and the contact portion C43.

The drive transistor Q₄ has the source region 12g and the drain region 12h at two sides of the gate-gate connection layer 21b. The source region 12g is connected to the V_{SS} wiring layer through the same route as that for the source region 12e from the contact portion C13 to the contact portion C43.

The load transistor Q₅ has the p⁺-type source region 12j and the p⁺-type drain region 12i at two sides of the gate-gate connection layer 21a, and the source region 12j is connected to the V_{DD} wiring film (corresponding to V_{DD} in FIG. 6) through the contact portion C19, the V_{DD} wiring layer 33, the contact portion C26, the V_{DD} contact pad layer 49, and the contact portion C44. The load transistor Q₆ has the p⁺-type source region 12l and the p⁺-type drain region 12k at two sides of the gate-gate connection layer 21b, and the source region 12l is connected to the V_{DD} wiring film through the same route as that for the source region 12j.

2. Advantages

The advantages of the semiconductor device according to this embodiment are as follows.

First, since the depth X of the element isolation region 19 and the width Y thereof which isolates the adjacent doped layers 12f and 12h from each other satisfy the equation represented by XY=1.33 to 1.67, while the doped layers 12f and 12h are being electrically isolated from each other, a stress per unit area applied to the semiconductor substrate 10 from the element isolation region 19 can be reduced. Accordingly, crystal defects can be prevented from being generated in the semiconductor substrate 10, and hence a semiconductor device can be obtained which has high reliability and which can reduce electrical power consumption.

Second, the element isolation region 19 can isolate the doped layers 12f and 12h from each other, which have the same conductivity. According to the structure described above, for example, even when a conductive layer (not shown) is formed in the vicinity of the two doped layers 12f and 12h, a parasitic bipolar transistor can be prevented from being formed from the two doped layers 12f and 12h and the conductive layer. As a result, stable electrical properties can be obtained. In particular, in this embodiment, the doped layers 12f and 12h having the same conductivity, which are contained in respective memory cells A100 adjacent to each other, can be isolated from each other (see FIGS. 2 and 7). According to the structure described above, the adjacent memory cells A100 can be electrically isolated from each other, and stable electrical properties can be obtained for the individual memory cells A100 adjacent to each other.

Third, the insulating layer 16 forming the element isolation region 19 may be formed by an HDP-CVD method, a TEOS plasma method, or an SOG method.

When the insulating layer 16 is formed by a TEOS plasma method or an SOG method, stress applied from the insulating layer 16 to the semiconductor substrate 10 is small as compared to that generated when the insulating layer is formed by an HDP-CVD method. Hence, crystal defects can be reliably prevented from being generated in the semiconductor substrate 10.

In addition, since an HDP-CVD method generally forms a dense insulating layer, when the insulating layer 16 is formed thereby, a large stress is applied to the semiconductor substrate 10 from the insulating layer 16 as compared to that generated when the insulating layer is formed by a TEOS plasma method or an SOG method. However, according to the semiconductor device of this embodiment, stress can be prevented from being concentrated at the joint portion between the insulating layer 16 and the semiconductor substrate 10. Hence, even when the insulating layer 16 is formed by an HDP-CVD method, crystal defects can be reliably prevented from being generated in the semiconductor substrate 10.

The present invention is not limited to the embodiment described above and may be variously modified. For example, the present invention may include a structure (for example, a structure having equivalent functions, methods, and advantages, or a structure having equivalent objects and advantages) substantially equivalent to that described in the embodiment. In addition, the present invention may also include a structure in which an unessential element among those described in the embodiment is replaced. In addition, the present invention may also include a structure having the same functions and advantages as those of the structure described in the embodiment or a structure which can achieve the same object as that described in the embodiment. Furthermore, the present invention may include a structure containing a known technique in addition to the structure described in the embodiment.

For example, although a solid semiconductor substrate is used for a semiconductor layer in the embodiment described above, an SOI substrate may also be used for a semiconductor layer.

The entire disclosure of Japanese Patent Application No. 2003-009933 filed Jan. 17, 2003 is incorporated by reference.

What is claimed is:

1. A semiconductor device comprising:
a semiconductor layer which contains an element isolation region and adjacent doped layers isolated from each other by the element isolation region,
wherein a depth X of the element isolation region and a width Y of the element isolation region satisfy an equation represented by X/Y=1.33 to 1.67.

2. The semiconductor device according to claim 1, wherein the depth of the element isolation region is in a range of 0.32 to 0.40 μm.

3. The semiconductor device according to claim 1,
wherein the element isolation region further comprises a trench element isolation region.

4. The semiconductor device according to claim 3, wherein the element isolation region comprises a trench formed in the semiconductor layer and an insulating layer provided in the trench.

5. The semiconductor device according to claim 4, wherein the insulating layer further comprises an HDP-CVD insulating layer.

6. The semiconductor device according to claim 4,
wherein the insulating layer further comprises a TEOS plasma CVD insulating layer.

7. The semiconductor device according to claim 4,
wherein the insulating layer further comprises an SOG insulating layer.

8. The semiconductor device according to claim 1,
wherein the adjacent doped layers further comprise two doped layers having the same conductivity.

9. The semiconductor device according to claim 1,
wherein the adjacent doped layers further comprise two doped layers which have the same conductivity and which are contained in respective memory cells adjacent to each other.

10. A semiconductor device comprising:
a semiconductor layer;
adjacent doped layers on the semiconductor layer; and
an element isolation region of the substrate isolating the adjacent doped layers from each other;
wherein a depth X of the element isolation region and a width Y of the element isolation region satisfy an equation represented by X/Y=1.33 to 1.67.

11. The semiconductor device according to claim 10, wherein the depth of the element isolation region is in a range of 0.32 to 0.40 μm.

12. The semiconductor device according to claim 10,
wherein the element isolation region further comprises a trench element isolation region.

13. The semiconductor device according to claim 12, wherein the element isolation region comprises a trench formed in the semiconductor layer and an insulating layer provided in the trench.

14. The semiconductor device according to claim 10,
wherein the adjacent doped layers further comprise two doped layers having the same conductivity.

15. The semiconductor device according to claim 10,
wherein the adjacent doped layers further comprise two doped layers which have the same conductivity and which are contained in respective memory cells adjacent to each other.
